(19) United States
(12) Patent Application Publication
(10) Pub. No.: US 2021/0053155 A1
(43) Pub. Date: Feb. 25, 2021

(54) CONNECTING ARTICLE AND METHOD FOR MANUFACTURING THE SAME, AND LASER DEVICE

(71) Applicant: SHENZHENSHI YUZHAN PRECISION TECHNOLOGY CO., LTD., Shenzhen (CN)

(72) Inventors: YOU-HONG TAN, Shenzhen (CN); CHENG-SHI CHEN, New Taipei (TW); CHAO ZHU, Shenzhen (CN)

(21) Appl. No.: 16/996,670

(22) Filed: Aug. 18, 2020

(30) Foreign Application Priority Data
Aug. 23, 2019 (CN) 201910785043.8

(51) Int. Cl. B23K 26/324; B23K 26/211; B23K 26/32; B23K 26/08; C23C 8/10

(52) U.S. Cl. CPC B23K 26/324; B23K 26/211; H05K 5/03; B23K 26/08; C23C 8/10; B23K 26/32

(57) ABSTRACT

A connecting article includes a non-metallic body and a bonding layer. The non-metallic body includes a non-metal. The bonding layer is bonded to the non-metallic body. The bonding layer includes the non-metal, a first alloy, and a second alloy. The present disclosure further provides a method for manufacturing the connecting article, and a laser device.

### FIELD

The subject matter relates to joining of heterogeneous materials, and more particularly, to a connecting article, a method for manufacturing the connecting article, and a laser device.

### BACKGROUND

Nonmetals include glass, ceramics, and plastics. Such nonmetallic material may be required to be joined to metallic material in various fields.

Glass has low toughness and low impact resistance, and joining glass and metal together increases the toughness and the impact resistance. However, since thermal expansion coefficients of glass and metal are quite different, thermal and residual stresses are generated at an interface of glass and metal, often creating a fatal weakness.

Furthermore, the poor surface wettability of glass also increases the difficulty in joining, the same thing also happens between ceramics and metal.

The connection of plastic and metal is relatively easy. However, low manufacturing cost and high connecting strength between plastic and metal seem to be mutually exclusive. Therefore, there is room for improvement in the art.

### BRIEF DESCRIPTION OF THE DRAWINGS

Implementations of the present technology will now be described, by way of example only, with reference to the attached figures.

FIG. 1 is a diagrammatic view of an embodiment of a non-metallic body.

FIG. 2 is a diagrammatic view showing a composite layer disposed on the non-metallic body of FIG. 1.

FIG. 3 is a diagrammatic view showing a first alloy disposed on the composite layer of FIG. 2.

FIG. 4 is a diagrammatic view of a connecting article formed by applying a laser treatment to the first alloy, the composite layer, and the non-metallic body of FIG. 3.

FIG. 5 is a diagrammatic view showing a process of the first alloy, the composite layer, and the non-metallic body of FIG. 4 melted and solidified under the laser treatment.

FIG. 6 is a diagrammatic view of an embodiment of a device including the connecting article.

FIG. 7 is a diagrammatic view of an embodiment of a surface treatment equipment.

FIG. 8 is a diagrammatic view of another embodiment of a surface treatment equipment.

FIG. 9 is a diagrammatic view of an embodiment of a laser device.

FIG. 10 is a diagrammatic view of an embodiment of “checkerboard” light emission paths.

FIG. 11 is a diagrammatic view of another embodiment of “checkerboard” light emission paths.

FIG. 12 is a flowchart of an embodiment of a method for manufacturing the connecting article.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

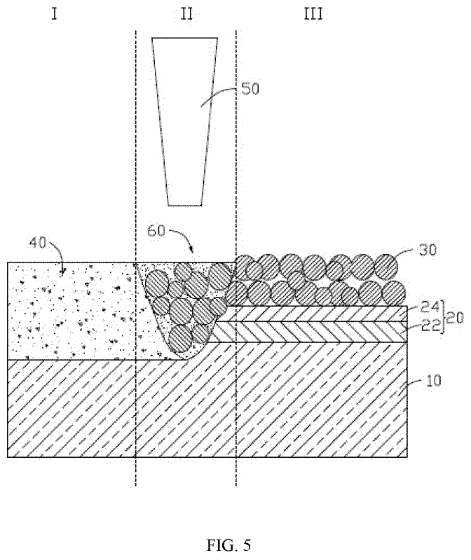

FIGS. 4 and 5 illustrate an embodiment of a connecting article 100, which includes a non-metallic body 10 and a bonding layer 40 disposed on the non-metallic body 10. The non-metallic body 10 includes a non-metal. The bonding layer 40 includes the non-metal, a first alloy 30, and a second alloy 22. The first alloy 30 and the second alloy 22 are different from each other.

The bonding layer 40 is formed by disposing the first alloy 30 and a composite layer 20 on the non-metallic body 10, and then melting the first alloy 30, at least a portion of the composite layer 20, and at least a portion of the non-metallic body 10 by a laser treatment. The composite layer 20 includes the second alloy 22 and an oxide layer 24 disposed on the second alloy 22.

Non-metal mean non-metallic materials, such as ceramics and plastics, having better surface wettability than glasses. When the non-metallic body 10 is made of glass, the composite layer 20 improves the connecting strength between the glass and the first alloy 30. Specifically, when the first alloy 30 is melted to form a liquid alloy, a surface tension between the liquid alloy and the composite layer 20 is less than a surface tension between the liquid alloy and the non-metallic body 10 when the composite layer 20 is absent. Thus, the composite layer 20 improves the surface wettability of the non-metallic body 10, thereby improving the connecting strength between the non-metallic body 10 and the first alloy 30.

The second alloy 22 may be at least one of iron-based alloy, aluminum-based alloy, titanium-based alloy, and nickel-based alloy. Referring to FIG. 5, the oxide layer 24 is oxidized by a portion of the second alloy 22. Specifically, the second alloy 22 is formed on the non-metallic body 10 through a metallization process. A portion of the second alloy 22 can be pre-oxidized to form the oxide layer 24.

In an embodiment, the second alloy 22 is iron-based alloy. The oxide layer 24 is iron oxide, such as ferrous oxide (FeO), ferric oxide (Fe₂O₃), tetra Ferric oxide (Fe₃O₄), a mixture of FeO and Fe₃O₄, or a mixture of Fe₃O₄ and Fe₂O₃. The composition of the oxide layer 24 also affects the surface wettability of the non-metallic body 10 and the first alloy 30. The oxide layer 24 being made of a mixture of iron oxides has a greater influence on the connecting strength between the non-metallic body 10 and the first alloy 30 than the oxide layer 24 being made of a single iron oxide. When the oxide layer 24 is made of a mixture of iron oxides, the connecting strength between the non-metallic body 10 and the first alloy 30 is greater.

In addition, the amount of the iron oxide in the oxide layer 24 also affects the surface wettability of the non-metallic body 10. For example, the lower the amount of Fe₃O₄ and the higher the amount of Fe₂O₃ in the oxide layer 24, the better the surface wettability of the non-metallic body 10.

The thickness of the composite layer 20 is in a range from 40 μm to 80 μm. If the thickness of the composite layer 20 is lower than 40 the strength of the composite layer 20 is insufficient. If the thickness of the composite layer 20 is over 80 μm, the laser energy cannot reach the non-metallic body 10, and the first alloy 30 cannot react with the composite layer 20 and the first alloy 30.

In an embodiment, the thickness of the oxide layer 24 is in a range from 2 μm to 10 μm. The thickness of the oxide layer 24 also affects the connecting strength of the non-metallic body 10 and the first alloy 30. When the thickness of the oxide layer 24 is increased, the connecting strength of the non-metallic body 10 and the first alloy 30 first increases but then gradually decreases. In an embodiment, the oxide layer 24 having the thickness of 2 μm to 10 μm significantly increases the connecting strength of the non-metallic body 10 and the first alloy 30.

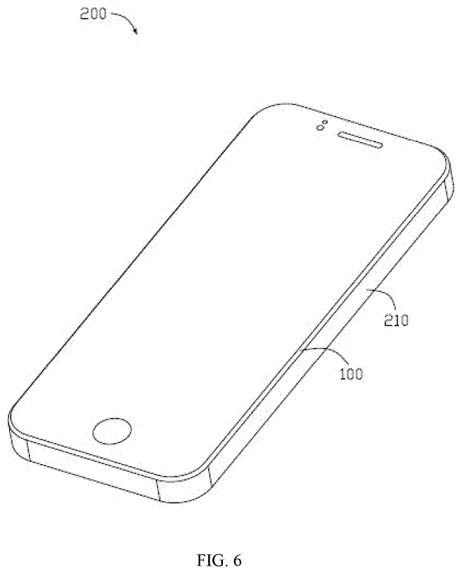

FIG. 6 illustrates an embodiment of a device 200, which includes a body 210 and the connecting article 100 disposed on the body 210. The device 200 may be an electronic device or a non-electronic device. The electronic device may include, but is not limited to, a mobile phone, a camera, and a computer. The non-electronic device may include, but is not limited to, a glass access control, a glass lamp, and a water glass.

In other embodiments, the device 200 may further include a metal element (not shown) disposed on the bonding layer 40 of the connecting article 100. The metal element may be formed on the bonding layer 40 by 3D printing. The metal element and the bonding layer 40 may be made of materials having similar physical and chemical properties.

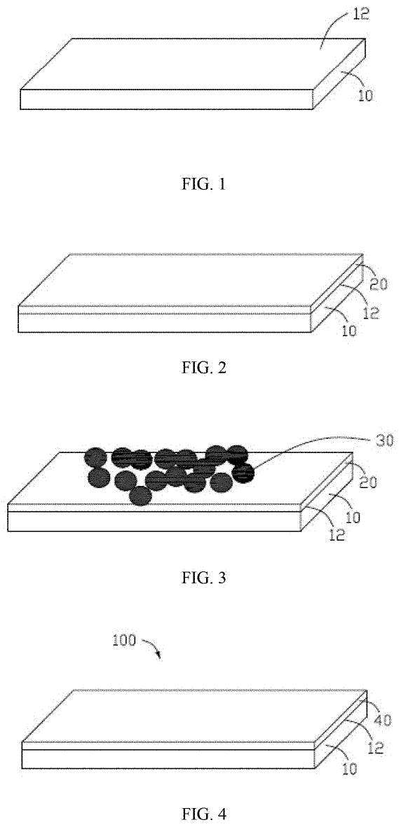

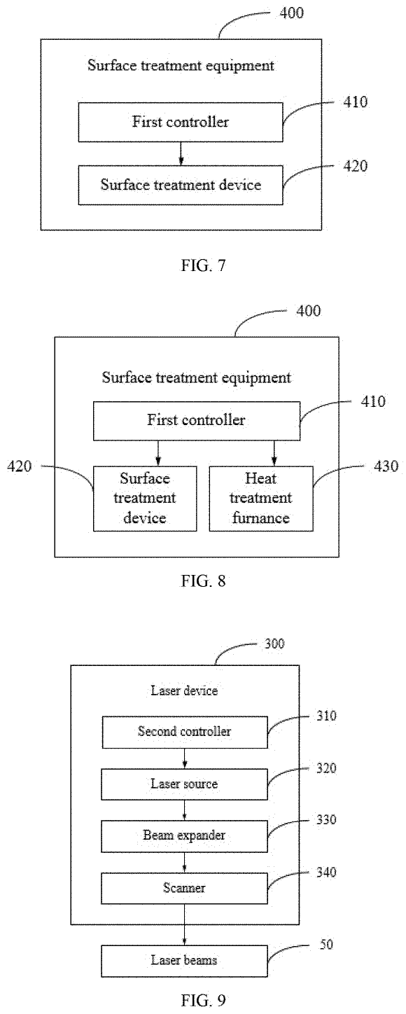

FIG. 7 illustrates an embodiment of a surface treatment equipment 400. The surface treatment equipment 400 includes a surface treatment device 420 and a first controller 410 coupled to the surface treatment device 420. The first controller 410 can control the surface treatment device 420 to perform a surface treatment on the non-metallic body 10. In an embodiment, the non-metallic body 10 includes a surface 12 (shown in FIGS. 1-4). The first controller 410 controls the surface treatment device 420 to form the composite layer 20 on the surface 12 of the non-metallic body 10.

The first controller 410 can control the surface treatment device 420 to change the processing procedure, thereby controlling the thickness of the composite layer 20 within the range from 40 μm to 80 μm. For example, the thickness of the composite layer 20 can be controlled to be 40 μm, 60 μm, or 80 μm.

Furthermore, the surface treatment device 420 can be at least one of a vacuum coating device, a magnetic particle sputtering device, a thermal spraying device, and a cold spraying device.

FIG. 8 illustrates another embodiment of the surface treatment equipment 400, which further includes a heat treatment furnace 430 coupled to the first controller 410. The heat treatment furnace 430 oxidizes the composite layer 20 formed on the non-metallic body 10.

The first controller 410 can control the heat treatment furnace 430 to change the heating temperature and heating period, thereby controlling the thickness of the oxide layer 24 within the range from 2 μm to 10 μm. For example, the thickness of the oxide layer 24 can be controlled to be 2 μm, 6 μm, 8 μm, or 10 μm.

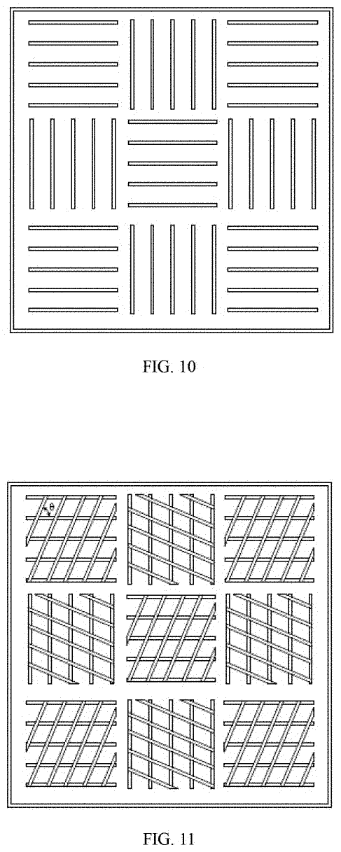

FIG. 9 illustrates an embodiment of a laser device 300 configured to connect the non-metallic body 10 and the first alloy 30 together. The laser device 300 includes a laser source 320 and a second controller 310 coupled to the laser source 320. The second controller 310 controls the laser source 320 to emit laser beams 50 (shown in FIG. 5). In the embodiment, the second controller 310 controls the laser source 320 to emit the laser beams 50 to the non-metallic body 10 containing the composite layer 20 and the first alloy 30, which melts the first alloy 30, at least a portion of the composite layer 20, and at least a portion of the non-metallic body 10.

The laser device 300 further includes a cavity (not shown), a beam expander 330, and a scanner 340. The cavity can receive an object. The beam expander 330 is connected to the laser source 320, and can adjust a diameter and a divergence angle of the laser beams 50 from the laser source 320. The scanner 340 is connected to the beam expander 330, and can apply the laser beams 50 from the beam expander 330 onto the object, thereby treating the surface of the object. In the embodiment, the laser source 320 is a fiber laser source. The object to be processed is the non-metallic body 10 containing the composite layer 20 and the first alloy 30.

The second controller 310 stores information as to a set of light emission paths. The second controller 310 can control the laser beams 50 to be emitted through at least one light emission path in the set. In an embodiment, the set of light emission paths includes a first light emission path and a second light emission path.

Furthermore, the set of light emission paths includes a first light emission path and a second light emission path, and an angle θ between the second light emission path and the first light emission path is in a range from 40 degrees to 80 degrees.

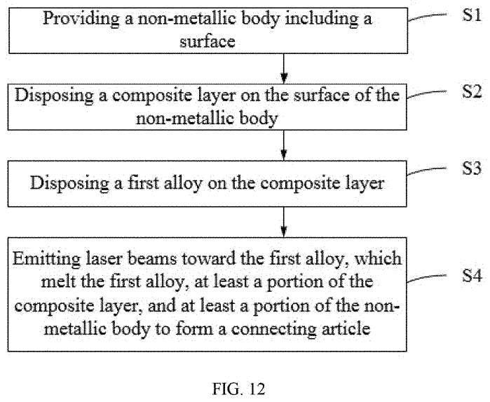

FIG. 12 illustrates an embodiment of a method for manufacturing the connecting article 100, the method can begin at block S1.

At block S1, referring to FIG. 1, the non-metallic body 10 is provided. The non-metallic body 10 has the surface 12. The non-metallic body 10 includes, but is not limited to, ceramics, glass, plastics, and polymers. The thickness of the non-metallic body 10 is such that the non-metallic body 10 is completely melted under a laser treatment. In an embodiment, the thickness of the non-metallic body 10 is in a range from 40 μm to 200 μm.

At block S2, referring to FIG. 2, the composite layer 20 is disposed on the surface 12 of the non-metallic body 10 through a surface treatment process. The surface treatment process may need to be performed multiple times on the surface 12. The surface treatment process may also be performed by dividing the surface 12 into various regions and separately treating different regions. Referring to FIG. 5, the composite layer 20 includes the second alloy 22 and the oxide layer 24. The oxide layer 24 is partially oxidized by the second alloy 22. Specifically, the second alloy 22 is first disposed on the non-metallic body 10 by a metallization process. The non-metallic body 10 containing the second alloy 22 is loaded into the heat treatment furnace 430, which oxidizes a portion of the second alloy 22 to form the oxide layer 24. The composite layer 20 improves the surface wettability of the non-metallic body 10, thereby improving the connecting strength of the non-metallic body 10 and the first alloy 30.

At block S3, referring to FIG. 3, the first alloy 30 is disposed on the composite layer 20. The first alloy 30 is in form of powders laid on the composite layer 20. When absorbing laser energy, the first alloy 30 is melted. The first alloy 30 and the composite layer 20 have similar physical and chemical properties, such as thermal expansion coefficient, thermal conductivity, and electrical conductivity. In an embodiment, the second alloy 22 is iron-based alloy, the first alloy 30 is stainless steel to match the iron-based alloy.

In an embodiment, the first alloy 30 has high purity, high sphericity or quasi-sphericity degree, small particle size, good powder flowability, and good powder spreadability. The high sphericity increases the powder flowability and the powder spreadability, which improves the uniformity of density of the connecting article 100, thereby ensuring the quality of the connecting article 100.

Furthermore, the particle size of the first alloy 30 is in a range from 15 μm to 53 μm. The first alloy 30 with a small particle size has a larger specific surface area, absorbing more laser energy under the laser treatment and being easily melted. Moreover, the first alloy 30 with a small particle size is more uniformly distributed on the composite layer 20, ensuring the quality of the connecting article 100. When the first alloy 30 has a small particle size, gaps between the powders are also small, and a high packing density is obtained. Thus, the connecting article 100 has a high density, which improves the strength and the surface quality of the connecting article 100. However, when the particle size of the first alloy 30 is too small, the powders of the first alloy 30 tend to adhere to each other, decreasing the powder flowability of the first alloy 30. Thus, uneven powder spreadability is the result, which affects the quality of the connecting article 100.

In an embodiment, the first alloy 30 includes powders of at least two particle sizes, that is, fine powders (for example, having a particle size of 25 μm) and coarse powders (for example, having a particle size of 40 μm) mixed in a certain ratio. Thus, the first alloy 30 combines advantages of both of the fine powders and coarse powders. The particle sizes of the fine powders and the coarse powders, and the ratio of mix can be varied according to actual need.

At block S4, referring to FIGS. 4 and 5, the laser beams 50 are emitted toward the first alloy 30, which melt the first alloy 30, at least a portion of the composite layer 20, and at least a portion of the non-metallic body 10, thereby connecting the non-metallic body 10 and the first alloy 30 together. The process of emitting the laser beams 50 toward the first alloy 30 and the melting the first alloy 30, at least a portion of the composite layer 20, and at least a portion of the non-metallic body 10 is selective laser melting (SLM).

Referring to FIG. 5, the non-metallic body 10, the composite layer 20, and the first alloy 30 are divided into three regions, that is, region I, region II, and region III in that order. Region III shows the non-metallic body 10, the composite layer 20, and the first alloy 30 before the laser treatment. When irradiated by the laser beams 50, the first alloy 30, at least a portion of the composite layer 20, and at least a portion of the non-metallic body 10 are melted to form a tiny molten pool 60, as shown in region II. After the laser treatment, the molten material in the molten pool 60 is solidified to form the bonding layer 40. The bonding layer 40 is connected to a remaining portion of the non-metallic body 10 which remains unmelted to form the connecting article 100, as shown in region I.

Furthermore, by controlling the energy density of the laser beams 50 through the second controller 310, the depth and the width of the molten pool 60 can be controlled. In an embodiment, the power of the laser source 320 is in a range from 160 W to 220 W. The scanning speed of the laser beams 50 is in a range from 800 mm/s to 1200 mm/s. The depth of the molten pool 60 is in a range from 0.1 mm to 0.4 mm.

The entire melting and solidification process may be completed in a very short time. The laser spot has high power density, which causes the target spot on the surface of the object to rapidly increase in temperature. The structure and the viscosity of the non-metallic body 10 are also rapidly changed. After the laser treatment, the temperature decreases, and the molten material rapidly solidifies. The rapid heating and solidification reduce residual stress at the connecting interface.

In an embodiment, the non-metallic body 10 is silicate glass. The second alloy 22 is iron-based alloy. The first alloy 30 is stainless steel. When irradiated by the laser beams 50 in an inert gas (such as argon) atmosphere, the silicon and oxygen elements in the silicate glass, and the iron element in the composite layer 20 and the first alloy 30, react to form a new phase Fe₂SiO₄, which is the key factor for tightly connecting the glass and the first alloy 30. Moreover, the surface composition of the glass changes under the laser treatment, for example, Na₂O, SiO₂, Al₂O₃, and other substances in the glass are significantly reduced. The carbon and iron elements in the first alloy 30 are oxidized. The physical and chemical properties of the glass and the first alloy 30 are quite different, but the composite layer 20 plays a key role in the connection between the composite layer 20 and the non-metallic body 10. By controlling the thickness and the composition of the composite layer 20, the connecting article 100 with a high quality can be obtained.

In an embodiment, block S3 and block S4 can be repeated a number of times (for example, 10 times to 20 times). That is, the first alloy 30 is disposed on the composite layer 20, and the SLM process is performed. Then, the first alloy 30 is again disposed on the composite layer 20 and another SLM process is performed. Finally, the first alloy 30, at least a portion of the composite layer 20, and at least a portion of the non-metallic body 10 are integrally connected.

Furthermore, the laser beams 50 can be emitted through at least one light emission path. Although only one light emission path is necessary for the laser melting process, excessive residual stress may be generated, and emitting the laser beams 50 through more than one light emission path reduces the residual stress.

Referring to FIGS. 10 and 11, the SLM process is performed through “checkerboard” light emission paths. That is, the surface to be processed (that is, the surface 12) is divided into multiple regions spaced from each other, such as multiple square regions of 5 mm*5 mm for example. Different regions are irradiated by the laser beams 50 one by one. Referring to FIG. 10, the bonding layer 40 is first formed on the entire surface 12. The bonding layer 40 can be formed by disposing the first alloy 30 on the entire surface 12, and irradiating the first alloy 30 on each region by the laser beams 50 through a first light emission path. The angle between the first light emission paths on adjacent regions is 90 degrees. The “checkerboard” light emission paths reduce residual stress in the connecting article 100, and prevent the melted material from separating from the unmelted non-metallic body 10 due to stresses arising during solidification.

Then, referring to FIG. 11, another bonding layer 40 is formed on the previous bonding layer 40. The another bonding layer 40 can be formed by disposing the first alloy 30 again on the entire surface 12, and irradiating the first alloy 30 on each region by the laser beams 50 through a second light emission path. The angle θ between the first light emission path and the second light emission path on the same regions is in a range from 40 degrees to 80 degrees. When the angle θ is less than 40 degrees or greater than 80 degrees, the scanning directions of the laser beams 50 for forming the bonding layers 40 on the same region are too close, which generates concentrations of stress. On the other hand, when the angle θ is in the range from 40 degrees to 80 degrees, the stresses are uniformly distributed, and the total residual stress is at a minimum. Thus, the smallest possible deformation of the connecting article 100 can be obtained. The density of the connecting article 100 reaches more than 99.9%. The bonding strength can also be increased. In operation, after forming the bonding layer 40 through the first light emission path, the second light emission path in the same region can be rotated by an angle θ based on the first light emission path. The angle θ can also be selected from 45 degrees, 50 degrees, 37 degrees, 70 degrees, and so on.

The method improves the surface wettability of the non-metallic body 10 by providing the composite layer 20 on the non-metallic body 10 during the bonding process. The connecting strength between the non-metallic body 10 and the first alloy 30 can also be increased. The materials of the composite layer 20 and the first alloy 30 are not limited, so the bonding layer 40 can be formed on different metal elements. The method is simple, which can be applied in various production processes.

### Example 1

A glass containing a composite layer was provided. A first alloy having a particle size of 15 μm to 53 μm was laid on the composite layer. The first alloy, a portion of the composite layer, and a portion of the glass was melted and then solidified to for the connecting article.

### Comparative Example 1

The difference from Example 1 is that the particle size of the first alloy is 5 μm to 15 μm. Other blocks are the same of Example 1.

### Comparative Example 2

The difference from Example 1 is that the particle diameter of the first alloy is 53 μm to 100 μm. Other blocks are the same of Example 1.

### Comparative Example 3

The difference from Example 1 is that the particle size of the first alloy is greater than 100 μm. Other blocks are the same of Example 1.

Table 1 shows manufacturing parameters and properties of the connecting articles of Example 1 and Comparative Examples 1-3. The properties include powder flowability, powder spreadability, density tested by cross-sectional metallographic analysis, surface roughness, and molded surface quality.

TABLE 1

| | | | | Thickness | | | |
|---|---|---|---|---|---|---|---|
| | Particle | Powder | Powder | of bonding | | | Surface |
| | size (μm) | flowability | spreadability | layer (μm) | Density | Strength | quality |
| Example 1 | 15-53 | Excellent | Excellen | 10-30 | 99.9% | Excellent | Excellent |
| Comparative | 5-15 | NG | NG | 10-30 | 70% | General | General |
| example 1 | | | | | | | |
| Comparative | 53-100 | Good | Good | 80-100 | 98% | General | General |
| example 2 | | | | | | | |
| Comparative | >100 | NG | NG | >100 | 20% | NG | NG |
| example 3 | | | | | | | |

From Table 1, making comparisons between powders of Comparative Example 1 being too small (particle size of 5 μm to 15 μm) and the powders of Comparative Example 2 (particle size of 53 μm to 100 μm) and Comparative Example 3 (particle size of more than 100 μm) being too large, the powders of Example 1 (particle size of 15 μm to 53 μm) have the best powder flowability and spreadability. By combining fine powders and coarse powders, gaps of the coarse powders are infilled by the fine powders, as in Example 1, so that the connecting article 100 has the highest density, the highest strength, and the best surface quality.

In addition, the connecting articles of Examples 2-21 were prepared. The qualities of the connecting articles of Examples 2-21 are controlled by changing the parameters of SLM process (that is, the laser power and laser scanning speed). The depth and the width of the molten pool were changed by changing the parameters of SLM process. Then, the properties of the connecting articles of Examples 2-21 were tested, and the test results were shown in Table 2. In Examples 2-21, the particle size of the first alloy was 15 μm to 53 μm. The power of the fiber laser source was 500 W. The laser power was 80 W to 240 W. The diameter of the laser spot was 80 mm to 120 mm. The laser scanning speed was 400 mm/s to 1600 mm/s. The inert atmosphere was argon gas.

TABLE 2

| | | Scanning | Depth of | Width of | |
|---|---|---|---|---|---|
| | Laser | speed | the molten | the molten | |
| | power (W) | (mm/s) | pool (μm) | pool (μm) | Quality |
| Example 2 | 80 | 400 | 35.52 | 105.2 | General |
| Example 3 | 80 | 800 | 26.52 | 78.03 | General |
| Example 4 | 80 | 1200 | 20.72 | 82.87 | Good |
| Example 5 | 80 | 1600 | 16.14 | 72.65 | Excellent |
| Example 6 | 120 | 400 | 111.93 | 145.56 | General |
| Example 7 | 120 | 800 | 57.58 | 131.84 | General |
| Example 8 | 120 | 1200 | 34.17 | 94.71 | General |
| Example 9 | 120 | 1600 | 28.25 | 82.87 | General |
| Example 10 | 160 | 400 | 167.62 | 165.2 | General |
| Example 11 | 160 | 800 | 107.62 | 146.1 | Good |
| Example 12 | 160 | 1200 | 68.07 | 113.81 | Good |
| Example 13 | 160 | 1600 | 52.74 | 99.55 | Good |
| Example 14 | 200 | 400 | 209.06 | 182.15 | General |
| Example 15 | 200 | 800 | 135.07 | 151.75 | Excellent |
| Example 16 | 200 | 1200 | 105.21 | 138.03 | Excellent |
| Example 17 | 200 | 1600 | 73.18 | 114.89 | Excellent |
| Example 18 | 240 | 400 | 266.37 | 183.5 | General |
| Example 19 | 240 | 800 | 168.7 | 152.83 | General |
| Example 20 | 240 | 1200 | 113 | 136.68 | General |
| Example 21 | 240 | 1600 | 86.91 | 115.16 | Good |

Moreover, connecting articles of Examples 22-33 and Comparative Examples 4-7 were prepared. The qualities of the connecting articles of Examples 22-33 and Comparative Examples 4-7 were controlled by controlling the thicknesses of the second alloy and the oxide layer of the composite layer. The particle size of the first alloy was 15 μm to 53 μm. The first alloy was stainless steel. The thickness of the glass was 2.0 mm-3.0 mm. The power of the fiber laser source was 500 W. The laser power was 200 W. The diameter of the laser spot was 80 mm to 120 mm. The scanning speed was 1200 mm/s. The glass containing the composite layer and the first alloy was heated to 200 degrees Celsius. The inert atmosphere was argon gas, including oxygen content of less than 100 ppm. Under laser energy, the first alloy, a portion of the composite layer, and a portion of the glass are quickly melted and solidified to obtain the connecting article. The properties of the connecting articles were tested, and the tested results were shown in Table 3. Furthermore, the thickness of the composite layer 20 is almost equal to the thickness of the second alloy 22 plus the thickness of the oxide layer 24.

TABLE 3

| | Thickness | Thickness | | |
|---|---|---|---|---|
| | of second | of oxide | | |
| | alloy (μm) | layer (μm) | Strength | Quality |
| Example 22 | 20 | 2 | NG | NG |
| Example 23 | 20 | 6 | General | General |
| Example 24 | 20 | 10 | General | General |
| Example 25 | 20 | 14 | NG | NG |
| Example 26 | 40 | 2 | General | General |
| Example 27 | 40 | 6 | Excellent | Excellent |
| Example 28 | 40 | 10 | Excellent | Excellent |
| Example 29 | 40 | 14 | Good | Good |
| Example 30 | 80 | 2 | Excellent | Excellent |
| Example 31 | 80 | 6 | Excellent | Excellent |
| Example 32 | 80 | 10 | Excellent | Excellent |
| Example 33 | 80 | 14 | Good | Good |
| Comparative | 100 | 2 | NG | NG |
| Example 4 | | | | |
| Comparative | 100 | 6 | NG | NG |
| Example 5 | | | | |
| Comparative | 100 | 10 | NG | NG |
| Example 6 | | | | |
| Comparative | 100 | 14 | NG | NG |
| Example 7 | | | | |

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A connecting article, comprising:
a non-metallic body comprising a non-metal; and
a bonding layer, being bonded to the non-metallic body and comprising the non-metal, a first alloy, and a second alloy.

2. The connecting article of claim 1, further comprising an oxide layer, formed on the second alloy.

3. The connecting article of claim 2, wherein the second alloy and the oxide layer constitute a composite layer, and a thickness of the composite layer is 40 μm to 80 μm.

4. The connecting article of claim 2, wherein a thickness of the oxide layer is 2 μm to 10 μm.

5. A laser device, configured to connect a first alloy to a non-metallic body, the non-metallic body comprising a surface, a composite layer disposed on the surface, the laser device comprising:
a laser source; and
a controller, coupled to the laser source and configured to control the laser source to emit laser beams toward the first alloy, causing the first alloy, at least a portion of the composite layer and at least a portion of the non-metallic body to be melted to form a bonding layer, and the bonding layer and the non-metallic body constituting a connecting article.

6. The laser device of claim 5, wherein the composite layer comprises a second alloy and an oxide layer, the oxide layer is formed on the second alloy.

7. The laser device of claim 6, wherein a thickness of the composite layer is 40 μm to 80 μm.

8. The laser device of claim 7, wherein a thickness of the oxide layer is 2 μm to 10 μm.

9. The laser device of claim 5, wherein the first alloy is sphericity or quasi-sphericity, and a particle size of the first alloy is 5 μm to 100 μm.

10. The laser device of claim 9, wherein the first alloy is sphericity or quasi-sphericity, and a particle size of the first alloy is 15 μm to 53 μm.

11. The laser device of claim 5, wherein the controller is configured to control the laser source to emit laser beam along at least a light emission path in a set of light emission paths.

12. The laser device of claim 11, wherein the set of light emission paths comprises a first light emission path and a second light emission path, and an angle between the second light emission path and the first light emission path is 40 degrees to 80 degrees.

13. A method for manufacturing a connecting article, the connecting article comprising a non-metallic body, the non-metallic body comprising a surface; the method comprising:
disposing a composite layer on the surface;
disposing a first alloy on the composite layer; and
emitting laser beam toward the first alloy, causing the first alloy, at least a portion of the composite layer, and at least a portion of the non-metallic body to be melted to form a bonding layer, and the bonding layer and the non-metallic body constituting the connecting article.

14. The method of claim 13, further comprising:
disposing a second alloy on the surface; and
oxidizing at least a portion of the second alloy to form the oxide layer, and the second alloy and the oxide layer constituting the composite layer.

15. The method of claim 14, wherein a thickness of the composite layer is 40 μm to 80 μm.

16. The method of claim 15, wherein a thickness of the oxide layer is 2 μm to 10 μm.

17. The method of claim 13, wherein the first alloy is sphericity or quasi-sphericity, and a particle size of the first alloy is 5 μm to 100 μm.

18. The method of claim 17, wherein the first alloy is sphericity or quasi-sphericity, and a particle size of the first alloy is 15 μm to 53 μm.

19. The method of claim 13, wherein the emitting comprises:
emitting laser beams along at least a light emission path in a set of light emission paths toward the first alloy, causing the first alloy, at least a portion of the composite layer, and at least a portion of the non-metallic body to be melt to form a bonding layer.

20. The method of claim 19, wherein the at least one light emission path comprises a first light emission path and a second light emission path, and an angle between the second light emission path and the first light emission path is 40 degrees to 80 degrees.
